(19) United States
(12) Patent Application Publication
(10) Pub. No.: US 2026/0040453 A1
(43) Pub. Date: Feb. 5, 2026

(54) SCREWLESS RETENTION DEVICE FOR COMPRESSION ATTACHED MEMORY MODULES

(71) Applicant: DELL PRODUCTS L.P., Round Rock, TX (US)

(72) Inventors: Arnold Thomas Schnell, Hutto, TX (US); Qinghong He, Austin, TX (US); Christopher A Torres, San Marcos, TX (US)

(21) Appl. No.: 18/789,955

(22) Filed: Jul. 31, 2024

(51) Int. Cl. H05K 1/18; G06F 1/18; H05K 1/02

(52) U.S. Cl. CPC H05K 1/18; G06F 1/187; H05K 1/0216; H05K 2201/10159

(57) ABSTRACT

A retention mechanism is provided to couple a compression attached memory module (CAMM) to a printed circuit board (PCB). The retention mechanism includes a retention bracket and a retention spring. The retention bracket is soldered by a solder flange to the PCB and retains a CAMM connector within the retention bracket. The retention spring retains the CAMM and compresses the CAMM onto the CAMM connector and the PCB.

### FIELD OF THE DISCLOSURE

This disclosure generally relates to information handling systems, and more particularly relates to a screwless retention device for compression attached memory modules (CAMMs) in an information handling system.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A retention mechanism may be provided to couple a compression attached memory module (CAMM) to a printed circuit board (PCB). The retention mechanism may include a retention bracket and a retention spring. The retention bracket may be soldered by a solder flange to the PCB and may retain a CAMM connector within the retention bracket. The retention spring may retain the CAMM and compress the CAMM onto the CAMM connector and the PCB.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is an exploded perspective view of a retention assembly for a compression attached memory module (CAMM) as may be known in the art;

FIG. 2A is an exploded perspective view of a retention assembly for a CAMM according to an embodiment of the present disclosure;

FIG. 2B is a side view of a retention bracket of the retention assembly of FIG. 2A;

FIGS. 3A-3F are perspective views of various embodiments of retention brackets that may be utilized in conjunction with the retention assembly of FIG. 2A;

FIG. 4A is an exploded perspective view of an embodiment of a bolster and retention bracket that may be utilized in conjunction with the retention assembly of FIG. 2A;

FIG. 4B is a perspective view of an embodiment of a portion of a retention bracket that can be utilized in conjunction with the bolster of FIG. 4A;

FIG. 5 is an exploded perspective view of another embodiment of a bolster and retention bracket that may be utilized in conjunction with the retention assembly of FIG. 2A;

FIGS. 6A and 6B are perspective views of a retention assembly for a CAMM according to another embodiment of the present disclosure;

FIG. 6C illustrates a retention paddle of the retention mechanism of FIGS. 6A and 6B;

FIG. 7 illustrates an exploded perspective view of a retention assembly for a CAMM according to another embodiment of the present disclosure; and

FIG. 8 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

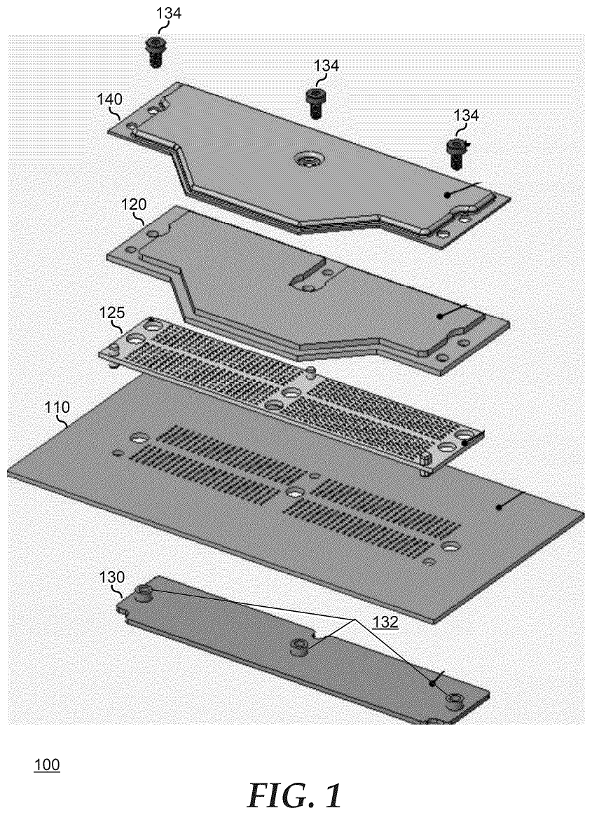

FIG. 1 illustrates a retention assembly 100 as may be known in the art. Retention assembly 100 includes a printed circuit board (PCB) 110, a CAMM 120, a CAMM connector 125, a bolster 130, and a retention bracket 140. Bolster 130 includes three (3) threaded binding posts 132 that are each aligned with associated through holes in PCB 110, CAMM 120, CAMM connector 125, and retention bracket 140. Retention assembly 100 is assembled to fasten and electrically connect CAMM 120 to PCB 110. In particular, bolster 130 is aligned such that each binding post 132 is aligned with the associated through holes in PCB 100, and is there affixed to the back side of the PCB. For example, bolster 130 can be affixed to PCB utilizing a double-stick mylar adhesive film (not illustrated), or the like. Bolster 130 can be affixed to PCB 110 in an assembly step that is separate from the installation of CAMM 120 to the PCB, or can be affixed when the CAMM is installed, as needed or desired.

When CAMM 120 is to be installed into PCB 110, CAMM connector 125 is aligned such that each through hole in the CAMM connector is aligned with the associated through hole of the PCB and with associated binding post 132. Then CAMM 120 is similarly aligned such that each through hole in the CAMM is aligned with the associated through hole of CAMM connector 125, with the associated through hole of PCB 110, and with associated binding post 132. Next retention bracket 140 is aligned such that each through hole in the retention bracket is aligned with the associated through hole of CAMM 120, with the associated through hole of CAMM connector 125, with the associated through hole of PCB 110, and with associated binding post 132. Finally screws 134 are placed through the aligned through holes of retention bracket 140, CAMM 120, CAMM connector 125, and PCB 110, and the screws are screwed into associated binding posts 132.

Screws 134 are tightened into binding posts 132 to a predetermined torque to ensure that CAMM connector 125 makes firm physical contact and sound electrical connections with PCB 110, and with CAMM 120. Note that as illustrated, retention bracket 140 is shaped to conformally cover the memory devices of CAMM 120 to provide an electromagnetic interference (EMI) shield element for the CAMM. Here, CAMM 120 may be provided with a ground ring around the periphery of the CAMM that acts to ground retention bracket 140 to provide adequate EMI shielding. Retention assembly 100 is illustrated as having three (3) binding posts 132 and three (3) screws 134, but this is not necessarily so, and a greater number or a lesser number of binding posts and screws can be utilized in affixing a CAMM to a PCB, as needed or desired.

It has been understood by the inventors of the current disclosure that the configuration of retention assembly 100 presents various associated challenges and difficulties. For example, the use of three (3) sets of aligned mounting holes in retention bracket 140, CAMM 120, CAMM connector 125, PCB 110, and binding posts 132 may not adequately spread the torque applied to screws 134 across CAMM connector 125 to sufficiently electrically connect CAMM 120 to PCB 110. For example, the regions of CAMM connector 125 that are located between screws 134 may bow upward or downward, thereby reducing the applied torque to the connector elements of the CAMM connector between the screws. Similarly, the applied torque may tend to warp or bow PCB 110, resulting in poor electrical connections between CAMM 120 and PCB 110. Moreover, the process of aligning the through holes of retention bracket 140, CAMM 120, and CAMM connector 125 with the through holes of PCB 110 and binding posts 132 can be difficult, resulting in misalignment between the connector elements of the CAMM connector and the connector pads of the CAMM and the PCB. Further, if any misalignment is rectified by torquing screws 134, such movement of the components into alignment may result in damaging the connector elements of CAMM connector 125. Moreover, due to the placement of the through holes along the short edges of CAMM 120 and retention bracket 140, and the lack of compression elements along the long edges of the CAMM, the retention bracket may make inadequate contact with the ground ring of the CAMM, leading to poor EMI shielding. Further, the center mount of retention bracket 140 has the potential of shorting to the PCB vias, traces or components. Finally, the mechanical tolerances inherent in retention assembly 100 may compete with the need for the retention bracket thickness to provide a firm attachment surface and compression force.

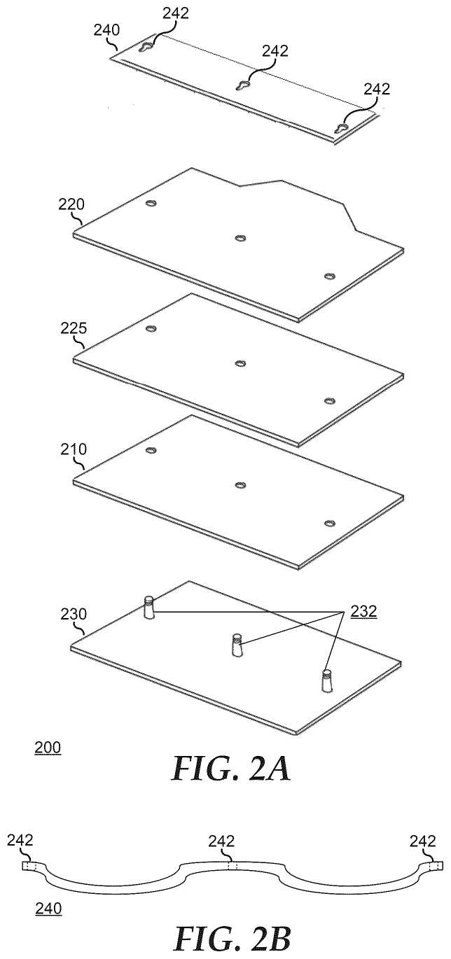

FIG. 2A illustrates an embodiment of a retention assembly 200. Retention assembly 200 includes a PCB 210, a CAMM 220, a CAMM connector 225, a bolster 230, and a retention bracket 240. Bolster 230 includes three (3) retention pins 232 that are each aligned with associated through holes in PCB 210, CAMM 220, CAMM connector 225, and retention bracket 240. The through holes are sized slightly larger than a diameter of retention pins 232, such that the retention pins slide easily into the through holes, but are not so oversized as to permit movement of PCB 210, CAMM connector 225, and CAMM 220 with respect to each other. Note that retention assembly 200 may include other elements that ensure proper alignment, and that my have finer tolerances than those of retention pins 232 and the through holes, as needed or desired. Retention assembly 200 is assembled to fasten and electrically connect CAMM 220 to PCB 210. In particular, bolster 230 is aligned such that each retention pin 232 is aligned with the associated through hole in PCB 200, and is there affixed to the back side of the PCB. For example, bolster 230 can be affixed to PCB utilizing a double-stick mylar adhesive film (not illustrated), or the like. Bolster 230 can be affixed to PCB 210 in an assembly step that is separate from the installation of CAMM 220 to the PCB, or can be affixed when the CAMM is installed, as needed or desired. It will be understood that, once bolster 230 is affixed to PCB 210, retention pins 232 will protrude from the top surface of the PCB, as described below.

When CAMM 220 is to be installed into PCB 210, CAMM connector 225 is installed such that each through hole in the CAMM connector is aligned with the associated retention pin 232. Then CAMM 220 is similarly installed such that each through hole in the CAMM is aligned with associated retention pin 232. In this way, retention pins 232 act as pilot pins, automatically aligning CAMM connector 225 and CAMM 220 with their proper orientation with respect to PCB 210. Retention bracket 240 includes three (3) retention slots 242 that are each aligned with associated through holes in CAMM 220, CAMM connector 225, and PCB 210, and with associated retention pins 232. Retention slots 242 are shaped with a larger diameter portion and a smaller diameter portion. Here, retention pins 232 are profiled with the larger diameter where the retention pins are placed through PCB 210, CAMM connector 225, and CAMM 220, with the smaller diameter where the retention pins are placed through retention bracket 240, and finally with the larger diameter where the retention pins protrude above the top of the retention bracket.

When retention bracket 240 is installed, the retention bracket is aligned such that the larger diameter portion of each retention slot 242 is aligned with the associated retention pin 232, the retention bracket is pushed downward to where the smaller diameter portion of the retention bracket engages with the smaller diameter region of the retention pin, and the retention bracket is slid sideways to engage the smaller diameter portion of the retention slot with the protruding portion of the retention pin. In this way, the larger diameter region of retention pins 232 that protrude above retention bracket 240 engages with the smaller diameter portion of retention slots 242 to secure retention assembly 200. The downward push on retention bracket 240 may be provided at a predetermined pressure that is sufficient to compress CAMM connector 225 to ensure sound electrical connection between CAMM 220 and PCB 210. As illustrated, retention bracket 240 is not shaped to conformally cover the memory devices of CAMM 220 to provide an EMI shield element for the CAMM, as shown above. However the shapes of the elements of retention assembly 200 are not meant to accurately portray a particularly shaped CAMM. As such, retention bracket 240 may be shaped to provide an EMI shield element for CAMM 220, as needed or desired. Retention assembly 200 is illustrated as having three (3) retention pins 232 and three (3) retention slots 234, but this is not necessarily so, and a greater number or a lesser number of retention pins and retention slots can be utilized in affixing a CAMM to a PCB, as needed or desired.

FIG. 2B shows retention bracket 240 having a profile that is curved such that the portions of the retention bracket between retention slots 242 are lower than the portions that include the retention slots. In this way, a greater pressure is applied to CAMM 220, CAMM connector 225, and PCB 210 to ensure better electrical connections between the CAMM and the PCB. The dimensions and shape of retention bracket 240 as depicted in FIG. 2A may be understood to be exaggerated to show the desired functionality, and other profiles may be utilized, as needed or desired.

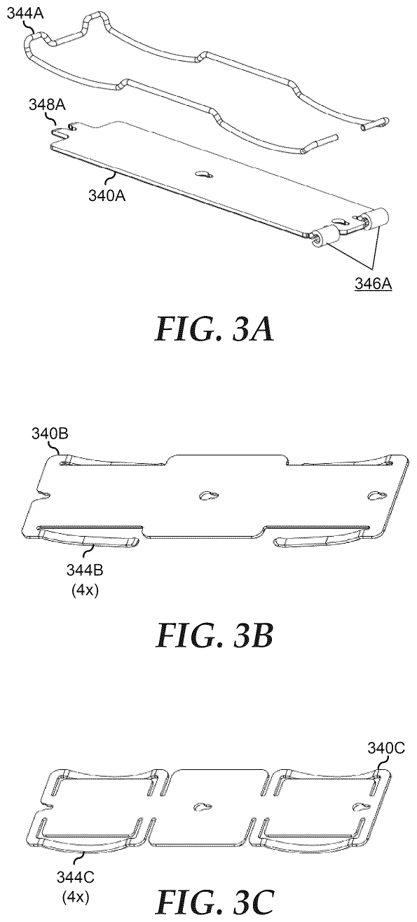

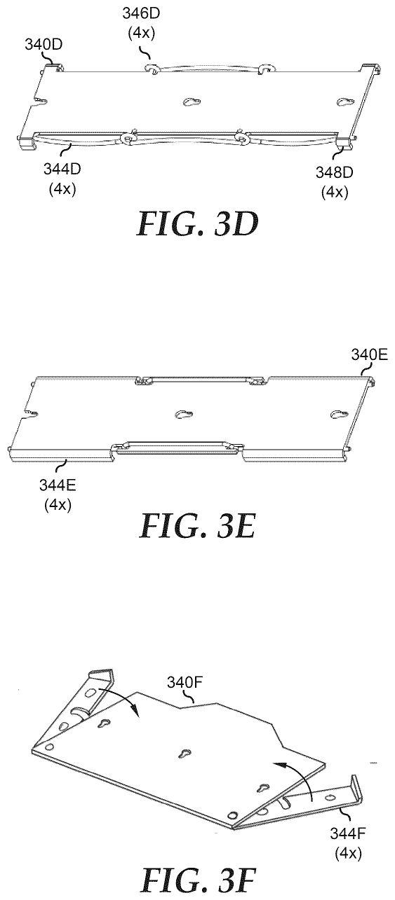

FIGS. 3A-3F illustrate retention brackets 340A-340F that are similar to retention bracket 240, and that may be utilized in conjunction with retention assembly 200 by substituting a selected one of retention brackets 340A-340F for retention bracket 240, as needed or desired. FIG. 3A illustrates spring assisted retention bracket 340A and an associated wireform retention spring 344A. Retention bracket 340A includes spring hinges 346A and spring latches 348A. Here, retention bracket 340A is assembled to a retention assembly as described above, being pushed onto the retention pins of the retention assembly, and slid to engage with the retention pins. Then hinge portions of retention spring 344A are engaged with spring hinges 346A and the retention spring is rotated to a closed position where latch portions of the retention spring are locked into place with spring latches 348A. Retention spring 344A is formed such that when in the closed position, the pressure is spread more evenly along the long edges of the associated CAMM.

FIG. 3B-3E illustrate spring assisted retention brackets 340B-340E that can be assembled to a retention assembly as described above by being pushed onto the retention pins of the retention assembly, and slid to engage with the retention pins. Retention brackets 340B-340E are similar to retention bracket 340A, in that they are all provided spring-like elements to engage directly with the surface of the CAMM. In FIG. 3B, retention bracket 340B includes four (4) integrated retention springs 344B that are integrated with the body of the retention bracket. In a particular embodiment, retention bracket 340B is fabricated as a single piece with retention springs 344B. For example, in a stamp-forging process, a die can be stamped out of a single piece of sheet metal, and the die can be forged to provide a sprung profile for retention springs 344B. Retention springs 344C are open-spring structures. In FIG. 3C, retention bracket 340C is similar to retention bracket 340B, including four (4) integrated retention springs 344C that are integrated with the body of the retention bracket. In a particular embodiment, retention bracket 340C is fabricated as a single piece with retention springs 344C, as described above. Here, retention springs 344C are closed-spring structures. Both of retention brackets 344B and 344C are configured to apply a spring force on the CAMM in the act of installing the retention brackets onto the retention assembly. This is in contrast to retention bracket 340A where the retention bracket is installed and then the force is applied to the CAMM when retention spring 344A IS closed.

In FIG. 3D, retention bracket 340D includes two (2) wireform retention springs 344D, with one affixed on each side of the retention bracket. Retention springs 344D are each installed on a side of retention backet 340D onto spring mounts 346D, and are retained in place by spring latches 348D. In a first case, retention bracket 340D is installed onto the retention assembly prior to the installation of retention springs 344D. In another case, retention springs 344D are installed onto retention bracket 344D prior to installing the retention bracket onto the retention assembly.

In FIG. 3E, retention bracket 340E includes four (4) load elements 344E that are formed as a single piece part with the retention bracket that provide a force to the CAMM. In FIG. 3F, retention bracket 340F includes two (2) retention latches 344F. Here, retention bracket 340F may be installed into the retention assembly as described above, with retention latches 344F in an open position, as illustrated. Then, retention latches 344F are moved to a closed position. Here, retention latches 233F each include one or more compression dimple that provides a downward force across the edge of the CAMM.

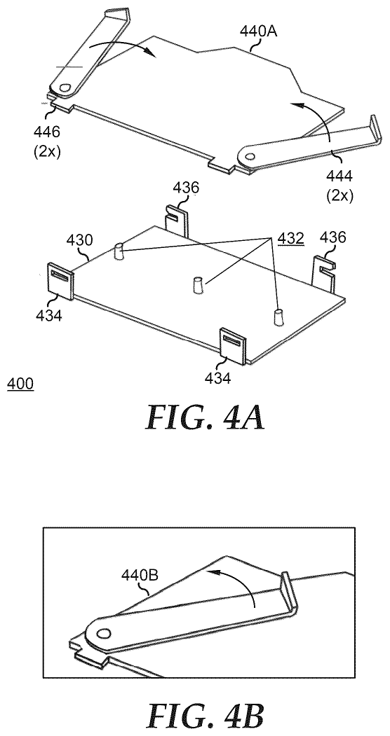

FIG. 4A illustrates portions of a retention assembly 400, similar to retention assembly 200. In particular, retention assembly 400 may be utilized to affix a CAMM similar to CAMM 200 and a CAMM connector similar to CAMM connector 225 to a PCB. However, the PCB associated with retention assembly 400 differs from PCB 200, as described further below. Here, FIG. 4A illustrates a bolster 430, and a retention bracket 440A.

Bolster 430 includes three (3) retention pins 432, two (2) tab receivers 434, and two (2) latch hooks 436. Retention pins 432 are similar to retention pins 232, except that retention pins 432 are shorter than retention pins 232. In this regard, retention pins 432 are provided to align bolster 430 with the PCB, the CAMM connector, and the CAMM, but are not long enough to provide a retention mechanism for retention bracket 440A. Here, retention bracket 440A is affixed to compress the CAMM and the CAMM connector through direct interaction with bolster 430, as described below. The PCB associated with retention assembly 400 is similar to PCB 200 in having holes that are each associated with one of retention pins 432. In addition, the PCB includes slots that are aligned with tab receivers 434 and latch hooks 436, and that permit the tab receivers and latch hooks to protrude through the PCB.

Retention bracket 440 includes two (2) retention latches 444 and two (2) retention tabs 446. Retention latches 444 are similar to retention latches 344 of retention bracket 340, as described above. In assembling retention assembly 400, bolster 430 is affixed to the back side of the associated PCB, with retention pins 432, tab receivers 434, and latch hooks 436 protruding through the top surface of the PCB. Next, the CAMM connector and the CAMM are aligned with retention pins 432. Finally, retention bracket 440A is engaged with bolster 430 by inserting retention tabs 446 into tab receivers 434, the retention bracket is rotated to compress the CAMM connector and the CAMM, and latches 444 are rotated to engage with and lock in to latch hooks 436.

FIG. 4B illustrates an alternate embodiment of retention bracket 440B. Retention bracket 440B is provided in contrast to retention bracket 440B. In this regard, note that latches 444 are rotated inward into latch hooks 436 which are slotted in an outward direction on retention bracket 440A. In contrast, latches 444 are rotated from the inside of retention bracket 440B outward into latch hooks that are slotted in an inward direction on the associated retention bracket. Here, retention bracket 440B may have an advantage over retention bracket 440A, in that latches 440, by rotating outward into the latch hooks, may not interfere with other elements on the PCB that are outside of the footprint of retention assembly 400.

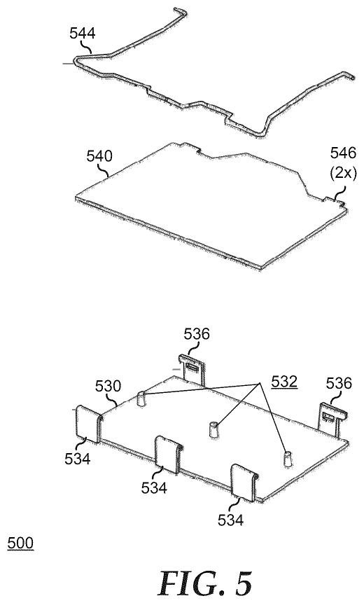

FIG. 5 illustrates portions of a retention assembly 500, similar to retention assembly 200. In particular, retention assembly 500 may be utilized to affix a CAMM similar to CAMM 200 and a CAMM connector similar to CAMM connector 225 to a PCB. However, the PCB associated with retention assembly 500 differs from PCB 200, but is similar to the PCB associated with retention assembly 400, as described further below. Retention assembly 500 includes a bolster 530 similar to bolster 430, and a retention bracket 540 with a retention spring 544.

Bolster 530 includes three (3) retention pins 532, three (3) spring hinges 534, and two (2) spring latches 536. Retention pins 532 are similar to retention pins 432, being shorter than retention pins 232, and are provided to align bolster 530 with the PCB, the CAMM connector, and the CAMM. Retention bracket 540 is affixed to compress the CAMM and the CAMM connector through direct interaction with bolster 430, as described below. The PCB associated with retention assembly 500 is similar to the PCB as described with respect to retention assembly 400, above, having holes that are each associated with one of retention pins 532, and slots that are aligned with tab receivers 434 and latch hooks 436, and that permit the tab receivers and latch hooks to protrude through the PCB.

Retention bracket 540 includes a retention spring 544 and two (2) retention tabs 546. In assembling retention assembly 500, bolster 530 is affixed to the back side of the associated PCB, with retention pins 532, spring hinges 534, and spring latches 536 protruding through the top surface of the PCB. Next, the CAMM connector and the CAMM are aligned with retention pins 532. Next, retention bracket 540 is engaged with bolster 530 by inserting retention tabs 546 into slots in spring latches 536, the retention bracket is rotated to compress the CAMM connector and the CAMM. Finally, retention spring 544 is affixed to spring hinges 534 and engaged with spring latches 536 to secure retention bracket 540 to bolster 530. In an alternate embodiment, retention assembly 500 may be utilized without the addition of retention bracket 540, and retention springs 544 may be utilized to apply pressure directly to the associated CAMM, as needed or desired.

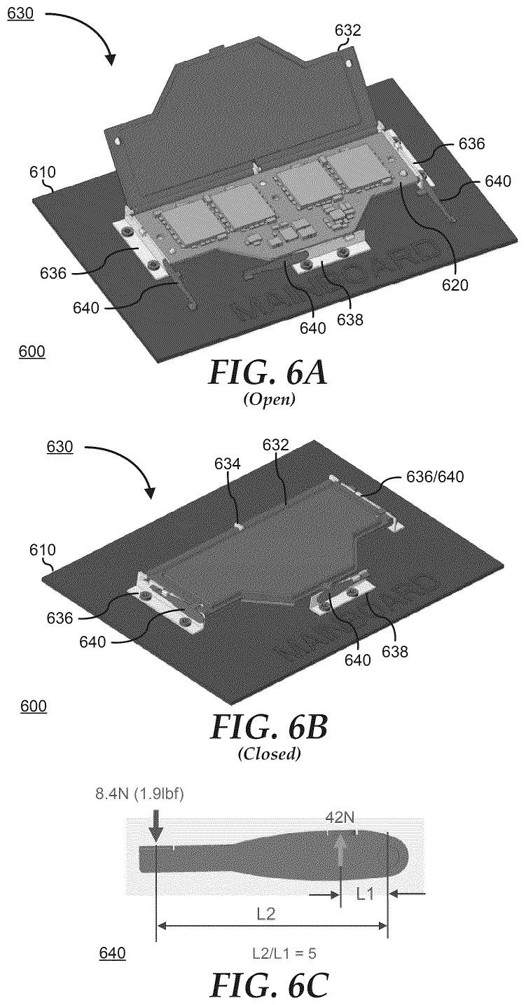

FIGS. 6A and 6B illustrate a retention assembly 600 for a CAMM 620 according to another embodiment of the present disclosure. Retention assembly 600 includes a PCB 610 and a retention bracket assembly 630. Retention bracket assembly 630 includes a retention cover 632, a retention tab 634, two (2) side retention hold-downs 636, a front retention hold-down 638, and three (3) retention paddles 640. Side retention hold-downs 636 and front retention hold-down 638 are mechanically affixed to PCB 610 such that, when CAMM 620 and an associated CAMM connector (not illustrated) are installed into retention bracket assembly 630, the CAMM and the CAMM connector are aligned properly with respect to the PCB. In this regard, one or more of side retention hold-downs 636 and front retention hold-down 638 may include guide structures that ensure the proper alignment of CAMM 620 and the CAMM connector. Side retention hold-downs 636 may operate to align CAMM 620 with respect to a first axis of PCB 610, and retention tab 634 and front retention hold-down 638 may operate to align the CAMM with respect to a second axis of the PCB that is perpendicular to the first axis.

In a particular embodiment, side retention hold-downs 636 and front retention hold-down 638 are mechanically affixed to PCB 610 with a bolster-and-screw arrangement, similar to retention assembly 100, as needed or desired. However, note that, in contrast to retention assembly 100, the installation and removal of CAMM 620 can be performed in retention assembly 600 without the need to remove the screws from side retention hold-downs 636 or front retention hold-down 638. In another embodiment, side retention hold-downs 636 and front retention hold-down 638 are mechanically affixed to PCB 610 by being soldered to pads on the PCB, as needed or desired.

Side retention hold-downs 636 include hinge mounts that movably affix retention cover 632 to the side retention hold-downs. As such retention cover 632 can be in an open position, as shown in FIG. 6A, or can be rotated to a closed position, as shown in FIG. 6B. Each one of side retention hold-downs 636 and front retention hold-down 638 include an associated one of retention paddles 640 that are movably affixed to their associated retention hold-downs. In particular, retention paddles 640 are in an open position when retention cover 632 is in the open position. Then, when CAMM 620 is installed into retention bracket assembly 630, and retention cover 632 is closed, retention paddles 640 are rotated to their closed position. Retention paddles 640 each include tabs that engage with retention cover 632 in the closed position to apply a downward pressure to compress CAMM 620 into the CAMM connector and PCB 610. Side retention hold-downs 636 and front retention hold-down 638 each include a hook configured to hold retention paddles 640 in the closed position. Further, when retention cover 632 is in the closed position, the back edge of the retention cover engages with retention tab 634 to apply a downward force at the back edge of CAMM 620.

FIG. 6C is a detailed view of retention paddle 640. Retention paddle 640 acts as a lever to increase a force applied at the end of the retention paddle to a larger force that is applied at the retention tab of the retention paddle. For example, the retention tab may be located at a length “L1” from a pivot point of retention paddle 640, and the end of the retention paddle may be located at a length “L2” from the pivot point. Where L2=5*L1, then the force applied at the retention tab will be five (5) times the force applied at the end of retention paddle 640. In a particular case, a force of 8.4 Newtons (N) (1.9 lbf) applied at the end of retention paddle 640 results in a downward force to compress CAMM 620 of 42 N (9.5 lbf) at the tab.

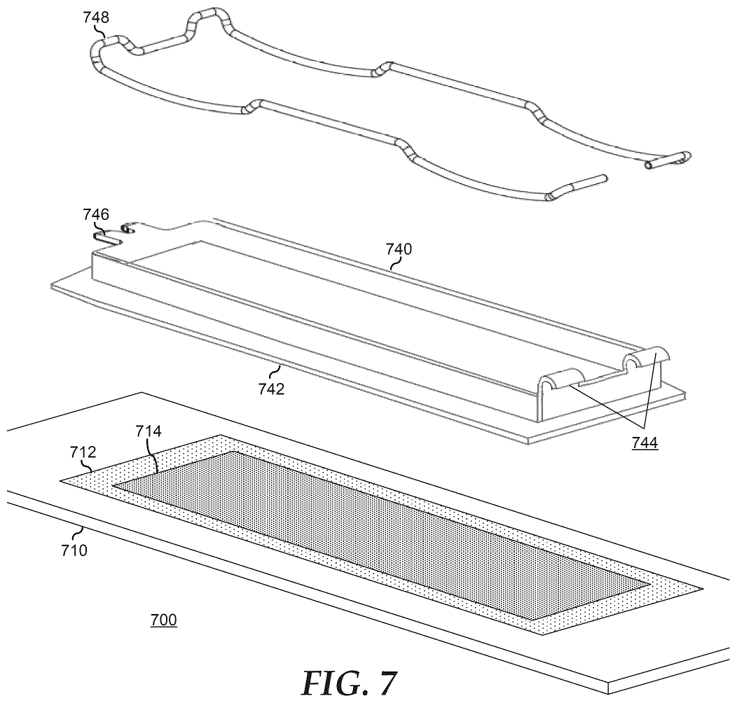

FIG. 7 illustrates a retention assembly 700. Retention assembly 700 includes a PCB 710 similar to PCBs 110, 210, and 610, and a retention bracket 740. PCB 710 includes a solder pad 712, and a CAMM connector pad array 714. Solder pad 712 is provided as a landing space to solder retention bracket 740 to PCB 710, as described further below. Pad array 714 represents the connector pads to which a CAMM connector are connected to PCB 710.

Retention bracket 740 includes a solder flange 742, spring hinges 744, a spring latch 746, and a wireform retention spring 748. Retention bracket 740 is assembled to PCB 710 at the time of PCB assembly. In particular, a solder paste can be applied to solder pad 712, and retention bracket 740 located on PCB 710 such that solder flange 742 is collocated with the solder pad, and a solder reflow process solders the retention bracket to the PCB. Then, when the information handling system is assembled, a CAMM connector is placed within retention bracket 740, and a CAMM is located atop the CAMM connector. Retention spring 748 is engaged with spring hinges 744, closed onto the CAMM, and hooked to spring latch to provide a consistent force across the CAMM to depress the CAMM onto the CAMM connector and onto PCB 710. In a particular embodiment, retention bracket 740 includes alignment features to ensure that the CAMM connector is aligned with PCB 710.

Note that a height of retention bracket 740 may be less than the height of the CAMM connector to permit the depression of spring contacts of the CAMM connector. Note further that solder pad 712 and solder flange 742 are illustrated as encompassing an entire perimeter of retention bracket 740. In a particular embodiment, solder pad 712 is connected to a ground plane of PCB 710 such that retention bracket 740 provides an EMI shield to the CAMM connector. In another embodiment (not illustrated), solder pad 712 and solder flange 742 are not formed to encompass the entire perimeter of the CAMM connector, as needed or desired.

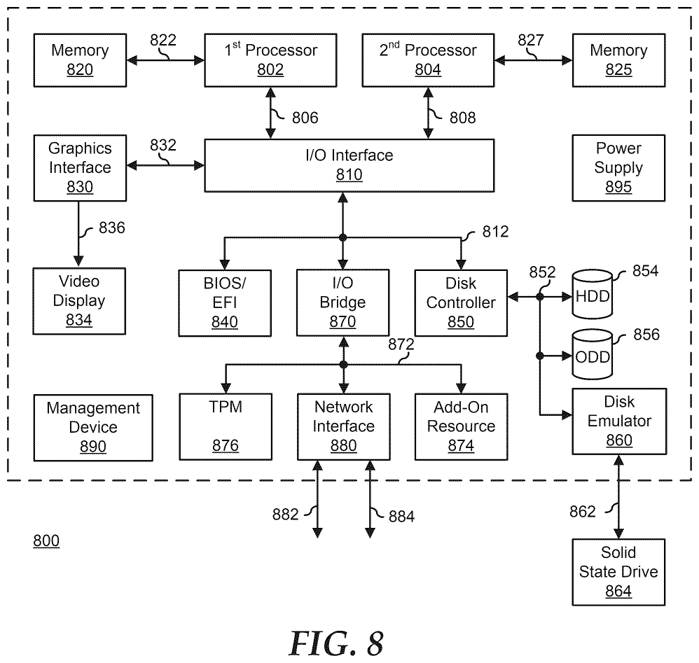

FIG. 8 illustrates a generalized embodiment of an information handling system 800 similar to information handling system 800. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 800 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 800 can include processing resources for executing machine-executable code, such as a central processing unit (CPU), a programmable logic array (PLA), an embedded device such as a System-on-a-Chip (SoC), or other control logic hardware. Information handling system 800 can also include one or more computer-readable medium for storing machine-executable code, such as software or data. Additional components of information handling system 800 can include one or more storage devices that can store machine-executable code, one or more communications ports for communicating with external devices, and various input and output (I/O) devices, such as a keyboard, a mouse, and a video display. Information handling system 800 can also include one or more buses operable to transmit information between the various hardware components.

Information handling system 800 can include devices or modules that embody one or more of the devices or modules described below, and operates to perform one or more of the methods described below. Information handling system 800 includes a processors 802 and 804, an input/output (I/O) interface 810, memories 820 and 825, a graphics interface 830, a basic input and output system/universal extensible firmware interface (BIOS/UEFI) module 840, a disk controller 850, a hard disk drive (HDD) 854, an optical disk drive (ODD) 856, a disk emulator 860 connected to an external solid state drive (SSD) 862, an I/O bridge 870, one or more add-on resources 874, a trusted platform module (TPM) 876, a network interface 880, a management device 890, and a power supply 895. Processors 802 and 804, I/O interface 810, memory 820, graphics interface 830, BIOS/UEFI module 840, disk controller 850, HDD 854, ODD 856, disk emulator 860, SSD 862, I/O bridge 870, add-on resources 874, TPM 876, and network interface 880 operate together to provide a host environment of information handling system 800 that operates to provide the data processing functionality of the information handling system. The host environment operates to execute machine-executable code, including platform BIOS/UEFI code, device firmware, operating system code, applications, programs, and the like, to perform the data processing tasks associated with information handling system 800.

In the host environment, processor 802 is connected to I/O interface 810 via processor interface 806, and processor 804 is connected to the I/O interface via processor interface 808. Memory 820 is connected to processor 802 via a memory interface 822. Memory 825 is connected to processor 804 via a memory interface 827. Graphics interface 830 is connected to I/O interface 810 via a graphics interface 832, and provides a video display output 836 to a video display 834. In a particular embodiment, information handling system 800 includes separate memories that are dedicated to each of processors 802 and 804 via separate memory interfaces. An example of memories 820 and 830 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 840, disk controller 850, and I/O bridge 870 are connected to I/O interface 810 via an I/O channel 812. An example of I/O channel 812 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 810 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 840 includes BIOS/UEFI code operable to detect resources within information handling system 800, to provide drivers for the resources, initialize the resources, and access the resources. BIOS/UEFI module 840 includes code that operates to detect resources within information handling system 800, to provide drivers for the resources, to initialize the resources, and to access the resources.

Disk controller 850 includes a disk interface 852 that connects the disk controller to HDD 854, to ODD 856, and to disk emulator 860. An example of disk interface 852 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 860 permits SSD 864 to be connected to information handling system 800 via an external interface 862. An example of external interface 862 includes a USB interface, an IEEE 1394 (Firewire) interface, a proprietary interface, or a combination thereof. Alternatively, solid-state drive 864 can be disposed within information handling system 800.

I/O bridge 870 includes a peripheral interface 872 that connects the I/O bridge to add-on resource 874, to TPM 876, and to network interface 880. Peripheral interface 872 can be the same type of interface as I/O channel 812, or can be a different type of interface. As such, I/O bridge 870 extends the capacity of I/O channel 812 where peripheral interface 872 and the I/O channel are of the same type, and the I/O bridge translates information from a format suitable to the I/O channel to a format suitable to the peripheral channel 872 where they are of a different type. Add-on resource 874 can include a data storage system, an additional graphics interface, a network interface card (NIC), a sound/video processing card, another add-on resource, or a combination thereof. Add-on resource 874 can be on a main circuit board, on separate circuit board or add-in card disposed within information handling system 800, a device that is external to the information handling system, or a combination thereof.

Network interface 880 represents a NIC disposed within information handling system 800, on a main circuit board of the information handling system, integrated onto another component such as I/O interface 810, in another suitable location, or a combination thereof. Network interface device 880 includes network channels 882 and 884 that provide interfaces to devices that are external to information handling system 800. In a particular embodiment, network channels 882 and 884 are of a different type than peripheral channel 872 and network interface 880 translates information from a format suitable to the peripheral channel to a format suitable to external devices. An example of network channels 882 and 884 includes InfiniBand channels, Fibre Channel channels, Gigabit Ethernet channels, proprietary channel architectures, or a combination thereof. Network channels 882 and 884 can be connected to external network resources (not illustrated). The network resource can include another information handling system, a data storage system, another network, a grid management system, another suitable resource, or a combination thereof.

Management device 890 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 800. In particular, management device 890 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 800, such as system cooling fans and power supplies. Management device 890 can include a network connection to an external management system, and the management device can communicate with the management system to report status information for information handling system 800, to receive BIOS/UEFI or system firmware updates, or to perform other task for managing and controlling the operation of information handling system 800. Management device 890 can operate off of a separate power plane from the components of the host environment so that the management device receives power to manage information handling system 800 where the information handling system is otherwise shut down. An example of management device 890 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 890 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A retention mechanism to couple a compression attached memory module (CAMM) to a printed circuit board (PCB), the retention mechanism comprising:
a retention bracket configured to be soldered by a solder flange to the PCB and to retain a CAMM connector within the retention bracket; and
a retention spring configured to retain the CAMM and to compress the CAMM onto the CAMM connector and the PCB.

2. The retention mechanism of claim 1, wherein the retention bracket further includes a spring hinge configured to hold the retention spring.

3. The retention mechanism of claim 2, wherein the retention bracket further includes a spring latch configured to retain the retention spring in a closed positon to retain the CAMM.

4. The retention mechanism of claim 1, wherein the solder flange is arranged around an entire perimeter of the CAMM connector.

5. The retention mechanism of claim 4, wherein the PCB includes a solder pad arranged around the entire perimeter.

6. The retention mechanism of claim 5, wherein the solder pad is coupled to a ground plane of the PCB, whereby the retention mechanism provides an electromagnetic interference shield for the CAMM connector.

7. The retention mechanism of claim 1, wherein the solder flange is arranged around a portion of a perimeter of the CAMM connector.

8. The retention mechanism of claim 7, wherein the PCB includes a solder pad arranged around the portion of the perimeter.

9. The retention mechanism of claim 1, wherein the retention bracket is shorter than a height of the CAMM connector.

10. The retention mechanism of claim 1, wherein the PCB includes a CAMM connector pad array.

11. A method for coupling a compression attached memory module (CAMM) to a printed circuit board (PCB), the method comprising:
soldering, by a solder flange of a retention bracket, the retention bracket to the PCB;
retaining, within the retention bracket, a CAMM connector;
retaining, by a retention spring coupled to the retention bracket, the CAMM to the retention bracket; and
compressing, by the retention spring, the CAMM onto the CAMM connector and the PCB.

12. The method of claim 11, wherein the retention bracket further includes a spring hinge configured to hold the retention spring.

13. The method of claim 12, wherein the retention bracket further includes a spring latch configured to retain the retention spring in a closed positon to retain the CAMM.

14. The method of claim 11, wherein the solder flange is arranged around an entire perimeter of the CAMM connector.

15. The method of claim 14, wherein the PCB includes a solder pad arranged around the entire perimeter.

16. The method of claim 15, wherein the solder pad is coupled to a ground plane of the PCB, whereby the retention mechanism provides an electromagnetic interference shield for the CAMM connector.

17. The method of claim 11, wherein the solder flange is arranged around a portion of a perimeter of the CAMM connector.

18. The method of claim 17, wherein the PCB includes a solder pad arranged around the portion of the perimeter.

19. The method of claim 11, wherein the retention bracket is shorter than a height of the CAMM connector.

20. An information handling system, comprising:
a printed circuit board; and
retention mechanism to couple a compression attached memory module (CAMM) to the PCB, the retention mechanism including:
a retention bracket configured to be soldered by a solder flange to the PCB and to retain a CAMM connector within the retention bracket; and
a retention spring configured to retain the CAMM and to compress the CAMM onto the CAMM connector and the PCB.
